(19) United States
(12) Patent Application Publication
(10) Pub. No.: US 2017/0034952 A1
(43) Pub. Date: Feb. 2, 2017

(54) FIXTURE DEVICE FOR HEAT-DISSIPATING MODULE AND HEAT-DISSIPATING MODULE HAVING FIXTURE DEVICE

(71) Applicant: TAI-SOL ELECTRONICS CO., LTD., TAIPEI CITY (TW)

(72) Inventors: Yun-Yeu YEH, TAIPEI CITY (TW); Chun-Huang CHOU, TAIPEI CITY (TW); Chien-Tung WANG, TAIPEI CITY (TW)

(21) Appl. No.: 14/932,274

(22) Filed: Nov. 4, 2015

(30) Foreign Application Priority Data
Jul. 31, 2015 (TW) 104124970

(51) Int. Cl. H05K 7/20

(52) U.S. Cl. CPC H05K 7/20418

(57) ABSTRACT

A fixture device includes an elongated body having at least two guide portions at two end sections thereof and a thread-coupling portion at a central section thereof, at least two latch members movably inserted through the guide portions to enable the guide portions move along axes of the latch members when the elongated body receives an external force, and an actuation bolt screwingly threaded through the thread-coupling portion and having an abutting part at a bottom thereof. Each latch member has a stop part to prevent the guide portions from upwardly escaping from the tops of the latch members. When being installed in a heat-dissipating module, the fixture device is combined with a heat-dissipating device which includes a bottom board and an integrated body formed by a plurality of fins, and the actuation bolt is inserted through a through hole passed through the center of the integrated body.

### BACKGROUND

1. Technical Field

The present invention relates to a heat-dissipating device for an electronic chip, and more particularly to a fixture device for a heat-dissipating module and a heat-dissipating module having a fixture device.

2. Description of Related Art

U.S. Pat. No. 7,903,411 disclosed a fixture device for a heat sink, wherein cooling fins are fixed on an electronic chip by a spring plate assembly. In the spring plate assembly, an actuation screw is disposed at the center of a spring plate and pressed on a bottom board by the spring plate and a spring pin slidable in a slot, and the pressing force applied on the bottom board can be adjusted by rotating the actuation screw. In such structure, the spring plate can be moved upwardly or downwardly in the direction of the spring pin sliding in the slot, but such structure has disadvantages of difficult assembly and a complicated structure.

### SUMMARY

A primary objective of the present invention is to provide a fixture device for a heat-dissipating module and the heat-dissipating module having the fixture device, wherein the fixture device can be used to fasten a heat-dissipating device on an electronic chip and is adjustable in the fastening force between the heat-dissipating device and the electronic chip. In addition, the structure of the present invention is different from and simpler than that of the traditional technology.

According to the primary objective, the present invention provides a fixture device for a heat-dissipating module. The fixture device includes an elongated body, at least two latch members and an actuation bolt. The elongated body has a top surface, a bottom surface, two end sections, at least two guide portions located at the two end sections, a central section, and a thread-coupling portion located at the central section. Each of the two end sections is provided with at least one guide portion. The at least two latch members are movably inserted through the at least two guide portions from the top surface of the elongated body toward the bottom surface of the elongated body, thereby enabling the at least two guide portions of the elongated body move along axes of the at least two latch members when the elongated body receives an external force. Each of the at least two latch members is provided at the top thereof with a stop part to prevent the at least two guide portions from upwardly escaping from the tops of the at least two latch members. The actuation bolt is screwingly threaded through the thread-coupling portion from the top surface of the elongated body toward the bottom surface of the elongated body, and has an abutting part at a bottom thereof.

Therefore, the fixture device can be used to fasten the heat-dissipating device on the electronic chip, and the fastening force between the heat-dissipating device and the electronic chip can be adjusted by rotating the actuation bolt. In addition, the structure of the fixture device of the present invention is different from and simpler than that of the traditional technology.

According to the primary objective, the present invention provides a heat-dissipating module including a heat-dissipating device, an elongated body, at least two latch members and an actuation bolt. The heat-dissipating device has a bottom board, and a plurality of fins disposed on the bottom board and integrated with each other to form an integrated body which has a through hole vertically passed through a center thereof. The elongated body is disposed over the bottom board and has a top surface, a bottom surface, two end sections, at least two guide portions located at the two end sections, a central section, and a thread-coupling portion located at the central section, and each of the two end sections is provided with at least one guide portion. The at least two latch members are movably inserted through the at least two guide portions from the top surface of the elongated body toward the bottom surface of the elongated body, thereby enabling the at least two guide portions of the elongated body move along axes of the at least two latch members when the elongated body receives an external force. Each of the at least two latch members has a stop part formed at the top thereof to prevent the at least two guide portions from upwardly escaping from the tops of the at least two latch members. The actuation bolt is screwingly threaded through the thread-coupling portion from the top surface of the elongated body toward the bottom surface of the elongated body, and inserted through the through hole of the heat-dissipating device. The actuation bolt is provided at the bottom thereof with an abutting part which is abutted against the bottom board.

Therefore, according to the present invention, the heat-dissipating device can be fastened on the electronic chip by the fixture device, and the fastening force between the heat-dissipating device and the electronic chip can be adjusted by rotating the actuation bolt. In addition, the structure of the fixture device of the present invention is different from and simpler than that of the traditional technology.

### BRIEF DESCRIPTION OF THE DRAWINGS

FIG. 1 is an exploded perspective view of a first preferred embodiment of the present invention.

FIG. 2 is an assembled perspective view showing a usage status of the first preferred embodiment of the present invention.

FIG. 3 is an exploded perspective view showing the usage status of the first preferred embodiment of the present invention.

FIG. 4 is a sectional view taken along the line 4-4 in FIG. 2.

FIG. 5 is an assembled perspective view showing another usage status of the first preferred embodiment of the present invention.

FIG. 6 is an exploded perspective view of FIG. 5.

FIG. 7 is an assembled perspective view showing a usage status of a second preferred embodiment of the present invention.

FIG. 8 is an exploded perspective view showing the usage status of the second preferred embodiment of the present invention.

FIG. 9 is a sectional view taken along the line 9-9 in FIG. 7.

FIG. 10 is an assembled perspective view showing a usage status of a third preferred embodiment of present invention.

FIG. 11 is an exploded perspective view showing the usage status of the third preferred embodiment of the present invention.

### DESCRIPTION OF THE EXEMPLARY EMBODIMENTS

The technical features of the present invention will be fully understood from the detailed description of preferred embodiments given herein below and the accompanying drawings.

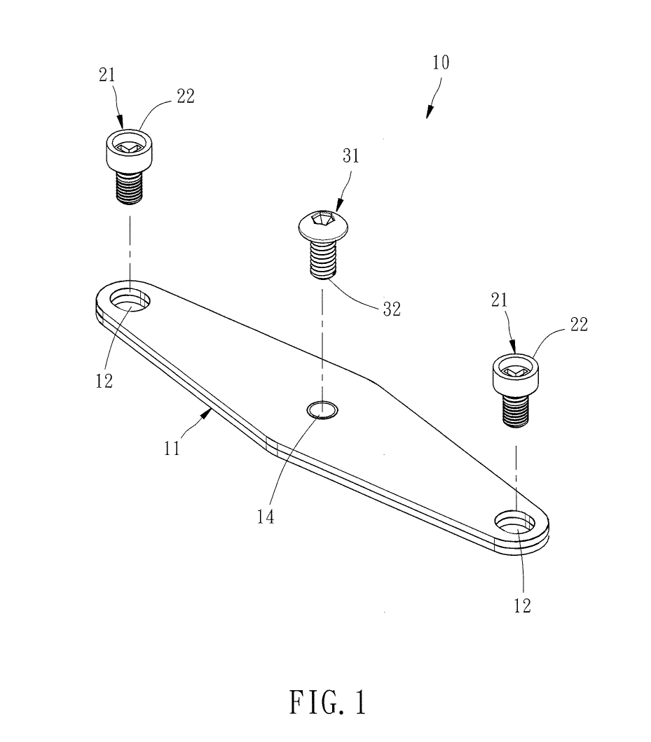

Please refer to FIG. 1 which illustrates a fixture device 10 for a heat-dissipating module according to a first preferred embodiment of the present invention. The fixture device 10 includes an elongated body 11, at least two latch members 21 and an actuation bolt 31.

The elongated body 11 has at least two guide portions 12 at two end sections thereof and a thread-coupling portion 14 at a central section thereof. Each of the two end sections of the elongated body 11 is provided with at least one guide portion 12. In the first embodiment, the at least one guide portion 12 is one in number and shaped as a through hole, and that is taken as an example. In addition, in the first embodiment, the elongated body 11 is formed with two stacked plates.

In the first embodiment, the at least two latch members 21 is two in number as an example. The two latch members 21 are movably inserted through the two guide portions 12 from a top surface of the elongated body toward a bottom surface of the elongated body, thereby enabling the two guide portions 12 move along axes of the two latch members 21 while the elongated body 11 receives an external force. Each latch member 21 has a stop part 22 at a top thereof, so that the two guide portions 12 are prevented from upwardly escaping from the tops of the two latch members 21.

The actuation bolt 31 is screwingly threaded through the thread-coupling portion 14 from the top surface of the elongated body toward the bottom surface of the elongated body, and has an abutting part 32 at a bottom thereof.

In the first embodiment, the fixture device 10 further includes a holder 41 which includes two bases 42, and the bottoms of the two latch members 21 are fastened to the two bases 42. In practice, each base 42 can be provided with a fastening hole 43, and the bottoms of the two latch members 21 are fastened to the two bases 42 by being inserted or screwed into the fastening holes 43.

The above description illustrates the structure of the first embodiment, and the operation of the first embodiment will be illustrated below.

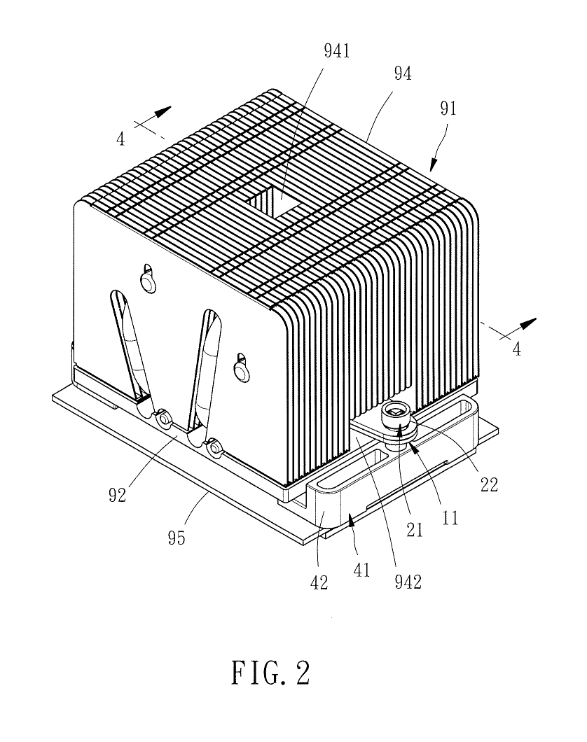

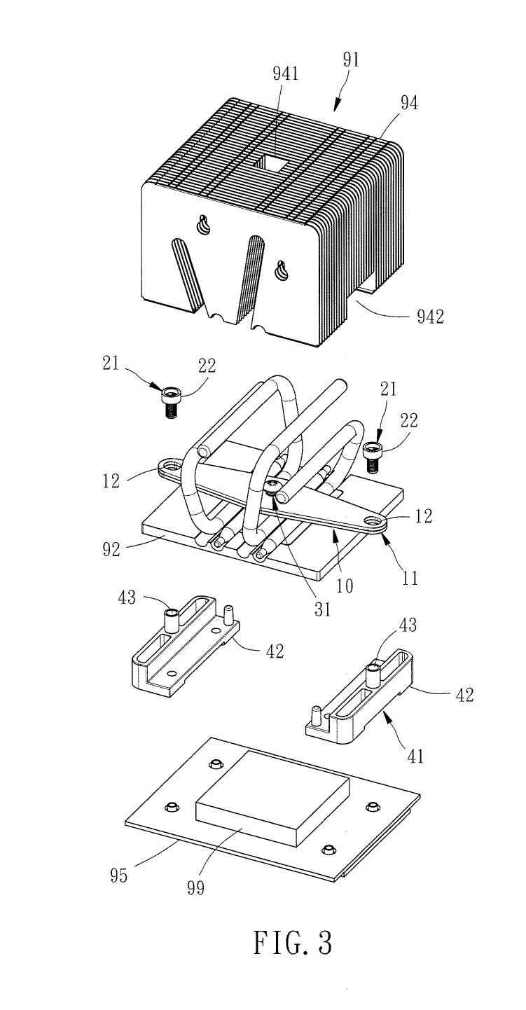

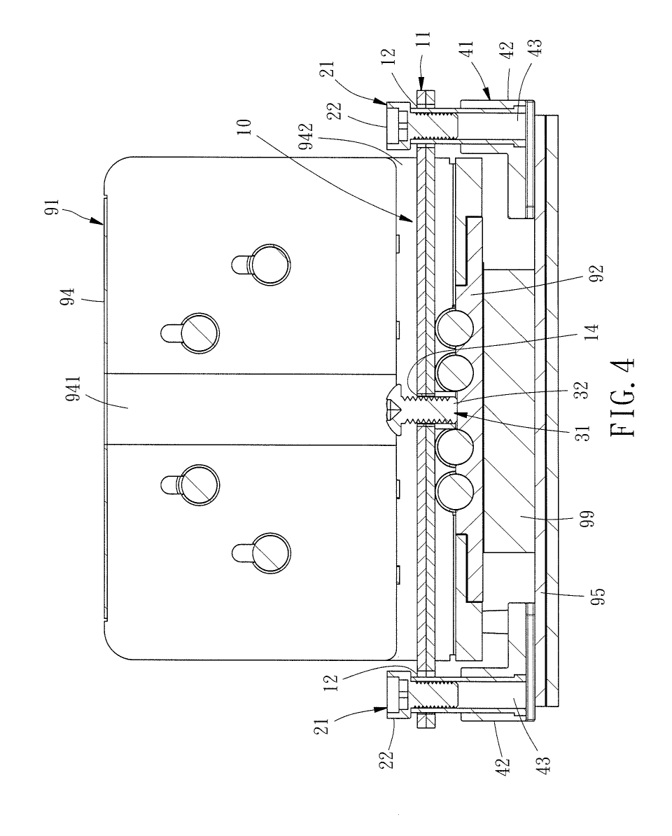

Referring to FIGS. 2-4, before the present invention is in use, the fixture device 10 and a heat-dissipating device 91 are combined on an electronic chip 99 (such as a CPU). The electronic chip 99 is disposed on a circuit board 95, and the two bases 42 of the holder 41 are disposed on the circuit board 95. The heat-dissipating device 91 includes a bottom board 92 and a plurality of fins 94 disposed on the bottom board 92. The fins 94 are integrated with each other to form an integrated body which has a through hole 941 vertically passed through the center thereof. The elongated body 11 is disposed in a receiving space 942 formed at the bottoms of the fins 94, and the elongated body 11 is located over the bottom board 92. The actuation bolt 31 is passed through the through hole 941 and screwed into the thread-coupling portion 14, and the abutting part 32 of the actuation bolt 31 is abutted against the bottom board 92. The bottoms of the two latch members 21 are fastened to the two bases 42. In this way, the heat-dissipating device 91 is combined with the electronic chip 99 by the fixture device 10 of the present invention.

While the present invention is in use, as shown in FIGS. 2-4, the height of the elongated body 11 can be adjusted by rotating the actuation bolt 31. Because the abutting part 32 of the actuation bolt 31 is abutted against the bottom board 92, the elongated body 11 is lifted when the actuation bolt 31 is screwed forwardly. When the two end sections of the elongated body 11 are in contact with the stop parts 22 of the two latch members 21, they can't be lifted anymore because the two latch members 21 are fastened to the two bases 42. At this time, if the actuation bolt 31 is still screwed forwardly, the central section of the elongated body 11 will be lifted but the two end sections of the elongated body 11 will not be lifted, so that the elongated body 11 will generate a downwardly restoring force which is applied on the actuation bolt 31 to press the bottom board 92 more so as to press the heat-dissipating device 91 on the electronic chip 99 tightly. By screwing the actuation bolt 31 forwardly or backwardly, the user can adjust the force applied by the actuation bolt 31 on the bottom board 92 so as to adjust the pressing force between the heat-dissipating device 91 and the electronic chip 99.

It should be noted that the amounts of the guide portion and the latch member are both two in the first embodiment, but the situations with more guide portions and latch members (ex. four latch members) are also practical. In the situation with four latch members, each of the two end sections of the elongated body is provided with two guide portions, which means each end section of the elongated body is provided with two holes, not one hole as shown in FIG. 2, and the elongated body has four guide portions in total; the four latch members are inserted through the four guide portions respectively and fastened to the bases. Such numerical variations are still within the scope of the claims of the present invention.

According to the above description, the fixture device 10 of the present invention can achieve the effects of fixing the heat-dissipating device 91 on the electronic chip 99 and being adjusted in the pressing force between the heat-dissipating device 91 and the electronic chip 99. In addition, the structure of the fixture device 10 of the present invention is different from and simpler than that of the conventional technology.

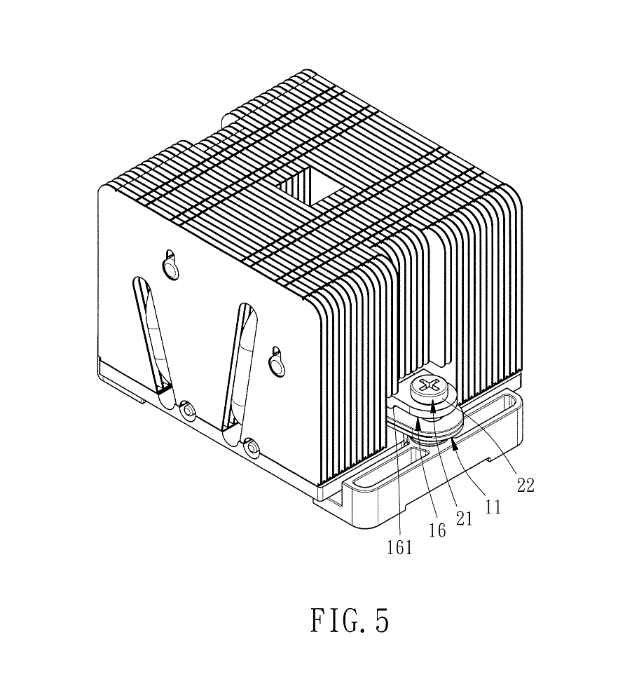

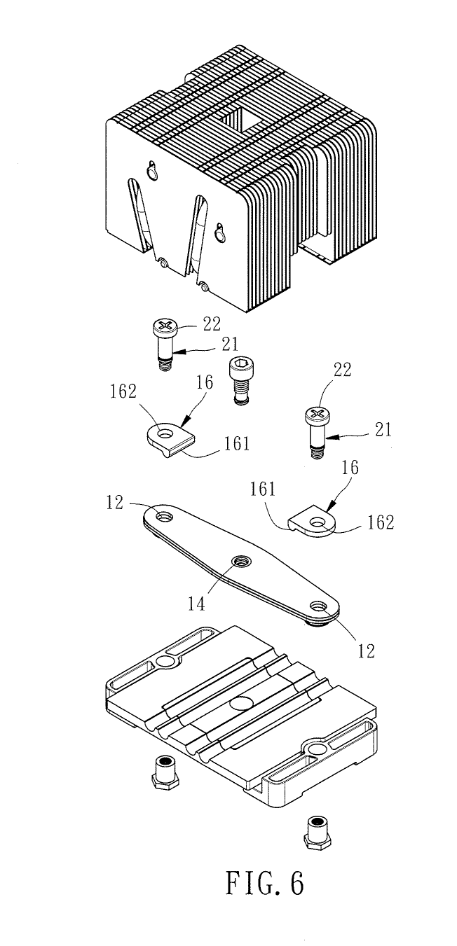

As shown in FIGS. 5 and 6, the fixture device 10 in the first embodiment can be further provided with two washers 16; the amount of the washer 16 corresponds to the amount of the latch member 21. Each washer 16 has an elongated protrusion 161 extended downwardly from a side thereof. Besides, each washer 16 has a through hole 162.

During assembly, the two latch members 21 are inserted through the through holes 162 of the two washers 16 to position the two washers 16 between the stop parts 22 of the two latch members 21 and the elongated body 11, and position the elongated protrusions 161 of the washers 16 between the guide portions 12 and the thread-coupling portions 14.

In this way, when the elongated body 11 is lifted and reaches the tops of the latch members 21, the two end sections of the elongated body 11 are abutted against the stop parts 22 of the two latch members 21 via the two washers 16, so that the pressing force applied by the stop parts 22 is transmitted to the elongated body 11 via the elongated protrusions 161 of the washers 16 and the other ends of the washers 16 opposite to the elongated protrusions 161. Therefore, the way of applying the pressing force from the two stop parts 22 to the elongated body 11 via the two washers 16 makes the force transmitted to a relatively larger area and relatively more locations, and prevents the elongated body 11 from deformation which may be caused by the single-point forces applied by the two stop parts 22 in the situation without the two washers 16.

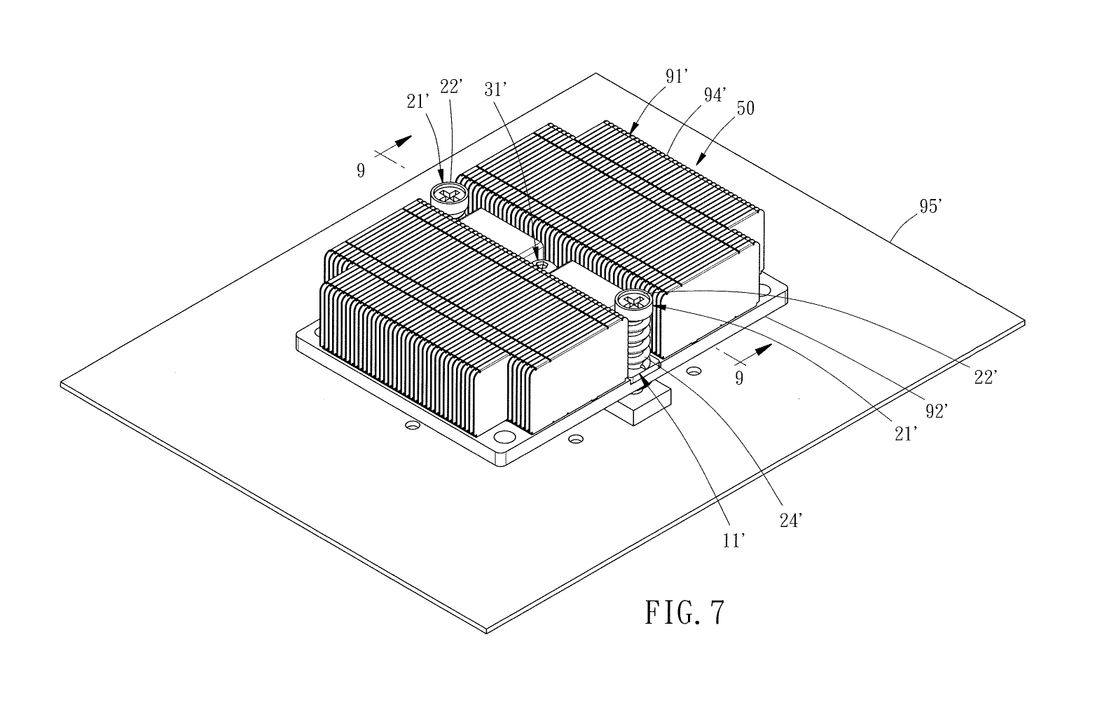

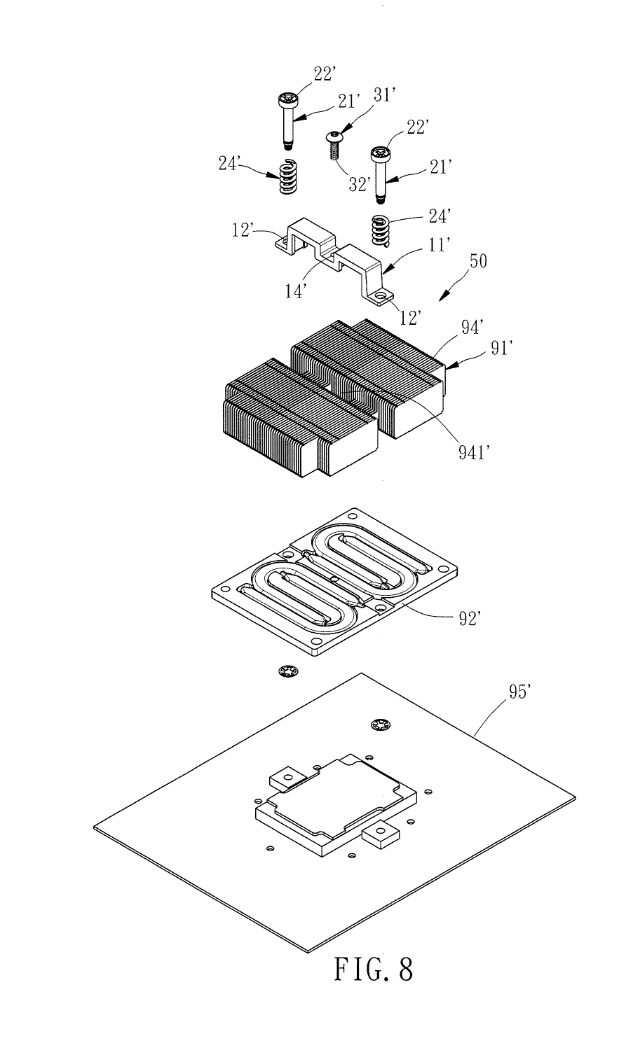

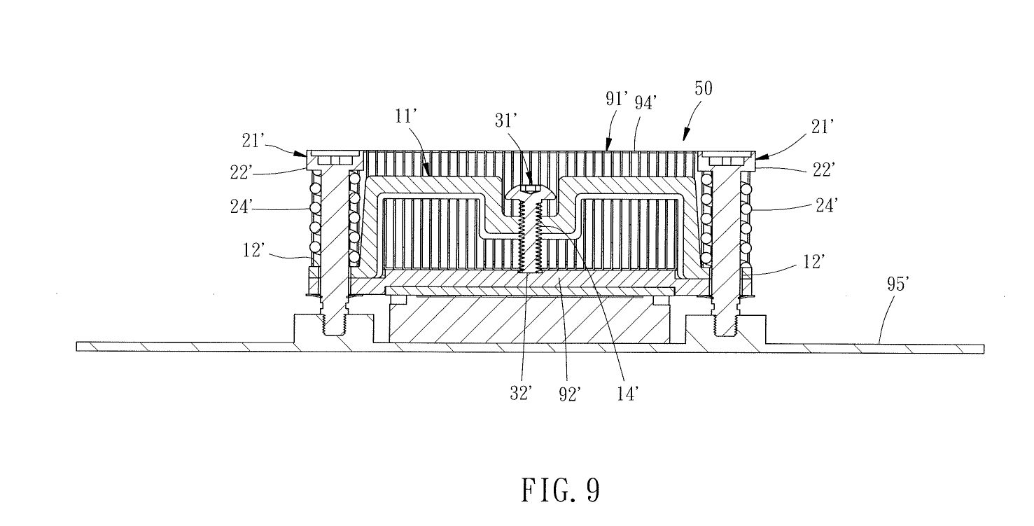

Referring to FIGS. 7-9, a heat-dissipating module 50 having a fixture device according to a second preferred embodiment of the present invention includes a heat-dissipating device 91′, an elongated body 11′, at least two latch members 21′, and an actuation bolt 31′.

The heat-dissipating device 91′ has a bottom board 92′ and a plurality of fins 94′ disposed on the bottom board 92′. A through hole 941′ is vertically passed through the center of the fins 94′.

The elongated body 11′ is located over the bottom board 92′, and has at least one guide portions 12′ at each of two end sections thereof and a thread-coupling portion 14′ at a central section thereof. In the second embodiment, the at least one guide portion 12′ at each end section of the elongated body 11′ is one in number as an example, and the elongated body 11′ is shaped as a bent plate. The two end sections of the elongated body 11′ are extended downwardly first and then extended outwardly and horizontally to form the guide portions 12 respectively, and the central section of the elongated body 11′ is bent downwardly to form the thread-coupling portion 14′. The elongated body 11′ is positioned on the fins 94′ of the heat-dissipating device 91′, and the thread-coupling portion 14′ is located in the through hole 941′ because of the downwardly bent structure of the central section of the elongated body 11′.

The at least two latch members 21′, which is two in number as an example in the second embodiment, are movably inserted through the two guide portions 12′ from the a surface of the elongated body toward a bottom surface of the elongated body, thereby enabling the two guide portions 12′ of the elongated body 11′ move along the axes of the two latch members 21′ while the elongated body 11′ receives an external force. Each of the two latch members 21′ has a stop part 22′ at a top thereof, to prevent the two guide portions 12′ from upwardly escaping from the tops of the two latch members 21′. In the second embodiment, the fixture device includes springs 24′ which are sleeved onto the latch members 21′ respectively and positioned between the stop part 22′ and the elongated body 11′.

The actuation bolt 31′ is screwingly threaded through the thread-coupling portion 14′ from the top surface of the elongated body toward the bottom surface of the elongated body and passed through the through hole 941′. The actuation bolt 31′ is provided at the bottom thereof with an abutting part 32′ which is abutted against the bottom board 92′.

During assembly, the latch member 21′ are directly fixed on a circuit board 95′, the actuation bolt 31 is screwed into the thread-coupling portion 14′ of the elongated body 11′ and then passed through the through hole 941′ to let the abutting part 32′ thereof abutted against the bottom board 92′, and other steps of the assembly is the same with that of the first embodiment.

In the operation of the second embodiment, when the elongated body 11′ is lifted, the pressing force is provided to the elongated body 11′ through the springs 24′. In this way, appropriate pressing force can be provided through the spring 24, and the problem of over pressure can be avoided.

Other effects of the second embodiment are substantially similar to that of the first embodiment, so their detailed descriptions are omitted.

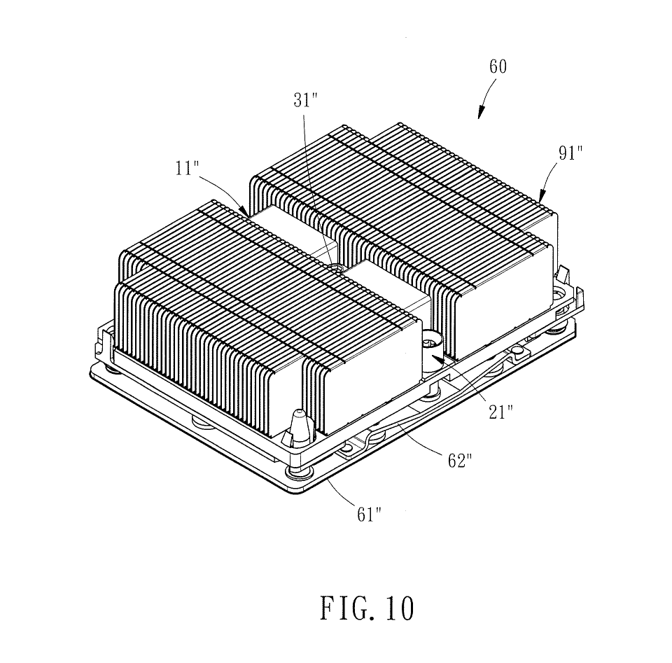

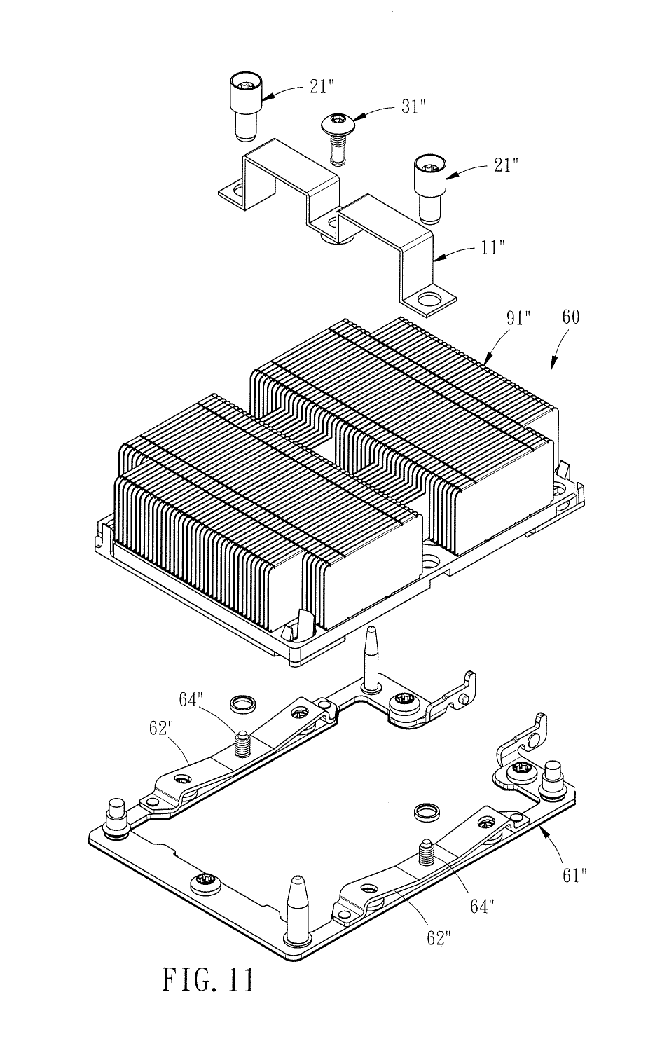

Referring to FIGS. 10 and 11, a heat-dissipating module 60 having a fixture device according to a third preferred embodiment of the present invention is similar to that of the second embodiment. The difference between the third preferred embodiment and the second preferred embodiment is that no such spring 24′ is sleeved onto any latch member 21″ of the third embodiment.

In addition to a heat-dissipating device 91″, an elongated body 11″, two latch members 21″ and an actuation bolt 31″, the heat-dissipating module 60 of the third embodiment further includes a resilient plate holder 61″, two resilient plates 62″ disposed on the resilient plate holder 61″ and corresponding in number to the two latch members 21″, and two thread-coupling members 64″ respectively fastened at the centers of the two resilient plates 62″. The two resilient plates 62″ are located correspondingly to the two latch members 21″ respectively. The two latch members 21″ have inner threaded troughs (not shown) formed at the bottoms thereof, which are screwed onto the two thread-coupling members 64″. By rotating the two latch members 21″ to move the thread-coupling members 64″ vertically, the two resilient plates 62″ can be actuated to move vertically. The higher the two resilient plates 62″ are lifted, the larger the restoring elastic force they generate to the elongated body 11″ so as to press the heat-dissipating device 91″ downwardly.

Other effects of the third embodiment are similar to that of the first embodiment, so their detailed descriptions are omitted.

What is claimed is:

1. A fixture device for a heat-dissipating module, comprising:
an elongated body having a top surface, a bottom surface, two end sections, at least two guide portions located at the two end sections, a central section, and a thread-coupling portion located at the central section, each of the two end sections being provided with at least one said guide portion;
at least two latch members movably inserted through the at least two guide portions from the top surface of the elongated body toward the bottom surface of the elongated body, thereby enabling the at least two guide portions of the elongated body to move along axes of the at least two latch members when the elongated body receives an external force, each of the at least two latch members being provided at a top thereof with a stop part to prevent the at least two guide portions from upwardly escaping from the tops of the at least two latch members; and
an actuation bolt screwingly threaded through the thread-coupling portion from the top surface of the elongated body toward the bottom surface of the elongated body, and having an abutting part at a bottom thereof.

2. The fixture device according to claim 1, further comprising springs, wherein each of the springs is sleeved onto one of the at least two latch members and positioned between the stop part and the elongated body.

3. The fixture device according to claim 1, wherein the elongated body is formed with two stacked plates.

4. The fixture device according to claim 1, wherein the elongated body is shaped as a bent plate; the two end sections of the elongated body are extended downwardly and then extended outwardly and horizontally to form the at least two guide portions; the central section of the elongated body is bent downwardly to form the thread-coupling portion.

5. The fixture device according to claim 1, further comprising a holder, and bottoms of the at least two latch members are fastened to the holder.

6. The fixture device according to claim 1, further comprising a resilient plate holder, at least two resilient plates disposed on the resilient plate holder and corresponding in number to the at least two latch members, and thread-coupling members respectively fastened on the resilient plates, wherein the at least two resilient plates are located correspondingly to the at least two latch members respectively; bottoms of the at least two latch members are abutted against the at least two resilient plates, thereby making the at least two resilient plates provide a restoring elastic force; the at least two latch members are screwed onto the at least two thread-coupling members.

7. The fixture device according to claim 1, further comprising washers corresponding in number to the at least two latch members, wherein each of the washers has an elongated protrusion extended downwardly from one side of the washer, and a through hole; the at least two latch members are respectively inserted through the through holes of the washers to position the washers between the stop parts of the at least two latch members and the elongated body, and position each of the elongated protrusions of the washers between one of the guide portions and the thread-coupling portion.

8. A heat-dissipating module, comprising:
a heat-dissipating device having a bottom board, and a plurality of fins disposed on the bottom board and integrated with each other to form an integrated body which has a through hole vertically passed through a center thereof;
an elongated body disposed over the bottom board and having a top surface, a bottom surface, two end sections, at least two guide portions located at the two end sections, a central section, and a thread-coupling portion located at the central section, each of the two end sections being provided with at least one said guide portion;
at least two latch members movably inserted through the at least two guide portions from the top surface of the elongated body toward the bottom surface of the elongated body, thereby enabling the at least two guide portions of the elongated body to move along axes of the at least two latch members when the elongated body receives an external force, each of the at least two latch members being provided at a top thereof with a stop part to prevent the at least two guide portions from upwardly escaping from the tops of the at least two latch members; and
an actuation bolt screwingly threaded through the thread-coupling portion from the top surface of the elongated body toward the bottom surface of the elongated body and inserted through the through hole of the heat-dissipating device, the actuation bolt being provided at a bottom thereof with an abutting part which is abutted against the bottom board.

9. The heat-dissipating module according to claim 8, further comprising springs, wherein each of the springs is sleeved onto one of the at least two latch members and positioned between the stop part and the elongated body.

10. The heat-dissipating module according to claim 8, wherein the elongated body is formed with two stacked plates.

11. The heat-dissipating module according to claim 8, wherein the elongated body is shaped as a bent plate; the two end sections of the elongated body are extended downwardly and then extended outwardly and horizontally to form the at least two guide portions; the central section of the elongated body is bent downwardly to form the thread-coupling portion.

12. The heat-dissipating module according to claim 8, further comprising a holder, and bottoms of the at least two latch members are fastened to the holder.

13. The heat-dissipating module according to claim 8, further comprising a resilient plate holder, at least two resilient plates disposed on the resilient plate holder and corresponding in number to the at least two latch members, and thread-coupling members respectively fastened on the resilient plates, wherein the at least two resilient plates are located correspondingly to the at least two latch members respectively; bottoms of the at least two latch members are abutted against the at least two resilient plates, thereby making the at least two resilient plates provide a restoring elastic force; the at least two latch members are screwed onto the at least two thread-coupling members.

14. The heat-dissipating module according to claim 8, further comprising washers corresponding in number to the at least two latch members, wherein each of the washers has an elongated protrusion extended downwardly from one side of the washer, and a through hole; the at least two latch members are respectively inserted through the through holes of the washers to position the washers between the stop parts of the at least two latch members and the elongated body, and position each of the elongated protrusions of the washers between one of the guide portions and the thread-coupling portion.
